(19) United States
(12) Patent Application Publication
(10) Pub. No.: US 2007/0052043 A1
(43) Pub. Date: Mar. 8, 2007

(54) Multilayer gate electrode, semiconductor device having the same and method of fabricating the same

(75) Inventors: Tae-Ho Cha, Seongnam-si (KR); Chang-Won Lee, Gwacheon-si (KR); Hee-Sook Park, Seoul (KR); Woong-Hee Sohn, Seocho-gu-Seoul (KR); Byung-Hee Kim, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/516,633

(22) Filed: Sep. 7, 2006

(30) Foreign Application Priority Data
Sep. 7, 2005 (KR) 10-2005-0083352

(51) Int. Cl. H01L 29/94; H01L 21/3205

(52) U.S. Cl. 257/412; 257/413; 438/585; 257/E29.126

(57) ABSTRACT

Example embodiments relate to a multilayer gate electrode, a semiconductor device having the same and methods of fabricating the same. Other example embodiments relate to a semiconductor device with a multilayer gate electrode which is relatively stable at higher temperatures, has improved resistance characteristics and improved reliability, and methods of fabricating the same. The multilayer gate electrode may include a polycrystalline semiconductor layer on the gate insulating layer and doped with conductive type impurities, an ohmic contact layer on the polycrystalline semiconductor layer and including tungsten (W₁₋ₓ) and non-tungsten metal (Mₓ, x=about 0.01 to about 0.55), a metal barrier layer on the ohmic contact layer and a refractory metal layer on the metal barrier layer. The semiconductor device including a conductive type transistor may include a semiconductor substrate, a conductive type source/drain region in the semiconductor substrate, a gate insulating layer on a channel region between the source/drain regions and the multilayer gate electrode.

### PRIORITY STATEMENT

This application claims priority under 35 U.S.C. § 119(a) to Korean Patent Application No. 10-2005-0083352, filed on Sep. 7, 2005, in the Korean Intellectual Property Office (KIPO), the entire contents of which are incorporated herein by reference.

### BACKGROUND

1. Field

Example embodiments relate to a multilayer gate electrode, a semiconductor device having the same and methods of fabricating the same. Other example embodiments relate to a semiconductor device having a multilayer gate electrode which is relatively stable at higher temperatures, has improved resistance characteristics and improved reliability, and methods of fabricating the same.

2. Description of the Related Art

As semiconductor devices have been highly integrated and a design rule of wiring lines has decreased below a sub-100 nm, there have been problems in RC delay of the wiring lines. A refractory metal, for example, tungsten, whose sheet resistance is about 2 to about 4 Ω/SQ, may be used to form wiring lines. A refractory metal layer may be used in forming a gate line and/or a bit line. When only a refractory metal layer is used in forming a gate line, a gate insulating layer may be polluted. A buffer gate line may be formed including polycrystalline silicon doped with impurities and a refractory metal line may be laminated thereon. A metal barrier layer may be formed in order to reduce the amount of silicidization of the refractory metal when a refractory metal layer is directly laminated on the polycrystalline silicon layer. An ohmic contact layer, for suppressing contact resistance of the refractory metal layer, may be interposed between the polycrystalline silicon layer and the refractory metal layer.

The ohmic contact layer, according to the related art, may function as a channel for diffusing outside impurities with which the polycrystalline silicon layer is doped. The ohmic contact layer also may cause an increase in sheet resistance of a gate electrode by a crystallization change of a gate metal to be deposited on the ohmic contact layer. For this reason, deterioration may be found in the C-V characteristic of a PMOS device. Because the ohmic contact layer according to the related art is unstable at relatively high temperatures, cohesion may occur during a thermal process and/or a void may be formed in the polycrystalline silicon layer.

### SUMMARY

Example embodiments relate to a multilayer gate electrode, a semiconductor device having the same and methods of fabricating the same. Other example embodiments relate to a semiconductor device with a multilayer gate electrode which is relatively stable at higher temperatures, has improved resistance characteristics and improved reliability, and methods of fabricating the same. Example embodiments are not limited to those mentioned above, and other example embodiments will be understood by those skilled in the art through the following description.

The multilayer gate electrode may include a polycrystalline semiconductor layer on a first gate insulating layer and doped with conductive type impurities, an ohmic contact layer on the polycrystalline semiconductor layer and including tungsten (W₁₋ₓ) and non-tungsten metal (Mₓ, x=about 0.01 to about 0.55), a metal barrier layer on the ohmic contact layer and a refractory metal layer on the metal barrier layer. The semiconductor device including a conductive type transistor may include a semiconductor substrate, a first conductive type source/drain region in the semiconductor substrate, the first gate insulating layer on a channel region between the source/drain regions and the multilayer gate electrode.

A second conductive type source/drain region may be formed in the semiconductor substrate and a second gate insulating layer may be formed on a channel region between the source/drain regions. The ohmic contact layer may have a ternary silicide layer including tungsten and non-tungsten metal on the interface with the polycrystalline semiconductor layer. The ohmic contact layer may be a ternary silicide layer including the tungsten and non-tungsten metal. The non-tungsten metal may be one selected from the group including Ti, Zr, and Hf. The refractory metal layer may be formed of at least one selected from the group including tungsten (W), rhenium (Re), tantalum (Ta), osmium (Os), molybdenum (Mo), niobium (Nb), vanadium (V), hafnium (Hf), zirconium (Zr), and titanium (Ti). The metal barrier layer may be formed of at least one selected from the group including WNₓ, TaNₓ, and TiNₓ. The channel region may be a channel region recessed in the semiconductor substrate.

According to other example embodiments, there is provided a method of fabricating a multilayer gate electrode. The method may include forming a polycrystalline semiconductor layer doped with conductive type impurities on a gate insulating layer, forming an ohmic contact layer including tungsten (W₁₋ₓ) and non-tungsten metal (Mx, x=about 0.01 to about 0.55) on the polycrystalline semiconductor layer, forming a metal barrier layer on the ohmic contact layer, forming a refractory metal layer on the metal barrier layer and completing a first conductive type transistor gate electrode by sequentially patterning the refractory metal layer, the metal barrier layer, the ohmic contact layer, the polycrystalline semiconductor layer doped with the first conductive type impurities, and the gate insulating layer. A method of fabricating a semiconductor device including a conductive type transistor may include providing a semiconductor substrate in which the gate insulating layer is formed and forming the multilayer gate electrode.

A polycrystalline semiconductor layer doped with second conductive type impurities may be formed on the gate insulating layer. The ohmic contact layer may be formed by depositing a composite target composed of tungsten and non-tungsten metal. The ohmic contact layer may be annealed so as to be silicidized. Forming the ohmic contact layer may include forming a bilayer including a tungsten layer and a non-tungsten metal layer on the polycrystalline semiconductor layer and annealing the bilayer. Forming the bilayer may include sequentially laminating the tungsten layer and the non-tungsten metal layer on the polycrystalline semiconductor layer. The thickness ratio (B/A) of the tungsten layer A and the non-tungsten metal layer B may be in a range of about 0.01 to about 1.2. Forming the ohmic contact layer may include forming the ohmic contact layer by a CVD method and/or an ALD method using tungsten source gas, non-tungsten metal source gas and/or silicon source gas.

The method of fabricating a semiconductor device may further include forming a capacitor after forming the conductive type transistor, forming wiring lines which allow electrical signals to be input to and output from the conductive type transistor, forming a passivation layer on the substrate and packaging the substrate. The non-tungsten metal may be any one selected from the group including Ti, Zr and Hf. The refractory metal layer may be formed of at least one of metals selected from the group including tungsten (W), rhenium (Re), tantalum (Ta), osmium (Os), molybdenum (Mo), niobium (Nb), vanadium (V), hafnium (Hf), zirconium (Zr), titanium (Ti). The semiconductor substrate may include a channel trench which is recessed.

### BRIEF DESCRIPTION OF THE DRAWINGS

Example embodiments will be more clearly understood from the following detailed description taken in conjunction with the accompanying drawings. FIGS. 1-10 represent non-limiting, example embodiments as described herein.

FIG. 1 is a diagram illustrating a semiconductor device including a planar channel transistor according to example embodiments;

FIG. 2 is a diagram illustrating the semiconductor device including a recess channel transistor according to example embodiments;

FIGS. 3-8 are diagrams illustrating a method of fabricating the semiconductor device including the planar channel transistor shown in FIG. 1;

FIGS. 9A-9C are images of a scanning electron microscope (SEM) illustrating an interface shape of a test sample fabricated according to example embodiments and a comparative sample; and

FIGS. 10A-10D are graphs illustrating a C-V characteristic of the test sample fabricated according to example embodiments and the comparative sample.

### DETAILED DESCRIPTION OF EXAMPLE EMBODIMENTS

Advantages and features of example embodiments may be understood more readily by referencing the following detailed description of example embodiments and the accompanied drawings. Example embodiments may, however, be embodied in many different forms and should not be construed as being limited to the embodiments set forth herein. Rather, these embodiments are provided so that this disclosure will be thorough and complete and will fully convey the concept of example embodiments to those skilled in the art, and example embodiments will only be defined by the appended claims. Well known process steps, device structures and techniques are not described in detail in some embodiments to avoid misinterpretation of example embodiments. Like reference numerals refer to like elements throughout the specification. Further, terms like “a first conductive type” and “a second conductive type” indicate conductive types opposite to each other (e.g., P type and/or N type). Each example embodiment, to be described below, may include complementary embodiments.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to a multilayer gate electrode, a semiconductor device having the same and methods of fabricating the same. Other example embodiments relate to a semiconductor device with a multilayer gate electrode which is relatively stable at higher temperatures, has improved resistance characteristics and improved reliability, and methods of fabricating the same.

FIG. 1 is a diagram illustrating a semiconductor device including a planar channel transistor according to example embodiments. With reference to FIG. 1, a semiconductor device having a multilayer structure may include a first conductive type transistor, for example, a PMOS transistor. The PMOS transistor may include a P type source/drain region 160 formed in a semiconductor substrate 101, a gate insulating layer 105 formed on a channel region 165 between the P type source/drain regions 160, and a gate electrode 135. The gate electrode 135 may be a multilayer gate electrode including a polycrystalline semiconductor layer 110P doped with P type impurities and a refractory metal layer 130, and further may include an ohmic contact layer 120 and a metal barrier layer 132 between the polycrystalline semiconductor layer 110P doped with P type impurities and the refractory metal layer 130. According to example embodiments, the polycrystalline semiconductor layer 110P may be a silicon based semiconductor layer, for example, a polycrystalline silicon layer. The polycrystalline semiconductor layer 110P may be formed at about 10 Å to about 2000 Å.

The refractory metal layer 130 may be formed of a relatively high fusion metal whose fusing point is above that of iron (about 1539° C.). The refractory metal layer 130 may be tungsten (W), rhenium (Re), tantalum (Ta), osmium (Os), molybdenum (Mo), niobium (Nb), vanadium (V), hafnium (Hf), zirconium (Zr) and/or titanium (Ti) may be used, but the high fusion metal is not limited thereto. For example, tungsten may be used as the refractory metal 130. This refractory metal layer 130 may be formed at about 10 Å to about 2000 Å. The metal barrier layer 132 may reduce silicidization of the refractory metal layer 130 with a subsequent heat treatment. The metal barrier layer 132 may be formed of a metal nitride (e.g., tungsten nitride, titanium nitride, tantalum nitride and/or boron nitride). The metal barrier layer 132 may have a thickness in the range of about 5 Å to about 3000 Å.

The ohmic contact layer 120 may lessen contact resistance between the polycrystalline semiconductor layer 110P and the refractory metal layer 130 and/or the metal barrier layer 132. According to example embodiments, the ohmic contact layer 120 may include tungsten (W₁₋ₓ) and a non-tungsten metal (Mₓ, x=about 0.01 to about 0.55). For example, the ohmic contact layer 120 may be a two-component metal layer including tungsten (W₁₋ₓ) and a non-tungsten metal (Mₓ, x=about 0.01 to about 0.55), a ternary silicide layer (MₓW₁₋ₓSi_{y}, x=about 0.01 to about 0.55) and/or a composite layer of these two layers. In the composite layer including the two-component metal layer and the three-component silicide layer, the silicide layer may be formed on the interface with the polycrystalline semiconductor layer 110N and 110P doped with impurities. The ohmic contact layer 120 may have a thickness in the range of about 5 Å to about 500 Å. Ti, Zr and/or Hf may be used as the non-tungsten metal M; however, the non-tungsten metal M is not limited thereto.

According to example embodiments, the atomic content (1−x) of tungsten included in the ohmic contact layer 120 may be larger than or the same as the atomic content (x) of the non-tungsten metal. A lower sheet resistance of the gate electrode may be obtained within this content range, and further, roughness may be reduced on the interface that is to be formed in the gate electrode, for example, between the ohmic contact layer and the polycrystalline semiconductor layer. Stability may be ensured during a thermal process. If x is less than about 0.01, a void may be formed due to the diffusion of silicon during the subsequent heat process. The amount of tungsten may increase which may deteriorate the reliability of the semiconductor device. If x is more than about 0.55, because the content of the non-tungsten metal increases, cohesion may occur due to the non-tungsten metal being present during a relatively high thermal process. A reaction may occur between non-tungsten metal and the polycrystalline semiconductor layer doped with impurities, which may deteriorate the inversion capacitance characteristics in the PMOS transistor. Example embodiments also take into account the content ratio of the above-described range. A hard mask layer 140 may be provided for forming the gate electrodes 135 and 137 and a spacer 150 may be formed.

According to example embodiments, the semiconductor device may be a second conductive type transistor, for example, including an NMOS transistor and a PMOS transistor. The NMOS transistor may include an N type source/drain region 162, a gate insulating layer 105 formed on a channel region 167 between the N type source/drain regions 162 and a gate electrode 137. The gate electrode 135 may be a multilayer gate electrode including a polycrystalline semiconductor layer 110N doped with N type impurities and the refractory metal layer 130. The gate electrode may further include the ohmic contact layer 120 and the metal barrier layer 132 between the polycrystalline semiconductor layer 110N doped with N type impurities and the refractory metal layer 130. Because the respective layers forming the gate electrode are substantially the same as those of the above-described PMOS transistor, further description is omitted.

According to example embodiments, the semiconductor device may include the gate electrodes 135 and 137 composed of polycrystalline semiconductor layers doped with different impurities, for example, dual polycrystalline semiconductor layers 110P and 110N. The PMOS transistor may use the gate electrode 135 including the polycrystalline semiconductor layer 110P doped with P type impurities and the NMOS transistor may use the gate electrode 137 including the polycrystalline semiconductor layer 110N doped with N type impurities. The gate electrode 135 of the PMOS transistor may be formed by using a polycrystalline semiconductor layer doped with N type impurities and the threshold voltage may be about 0.7V. If the gate electrode 135 for PMOS transistor is formed by using a polycrystalline semiconductor layer doped with P type impurities, the threshold voltage may decrease to about 0.55V. When both polycrystalline semiconductor layers 110P and 110N are used, characteristics of the transistor may be improved. The polycrystalline semiconductor layer 110P, doped with P type impurities, may be a polycrystalline semiconductor layer doped with P type impurities and N type impurities whose concentration is lower than that of the P type impurities. The polycrystalline semiconductor layer 110N, doped with N type impurities, may be a polycrystalline semiconductor layer exclusively doped with N type impurities.

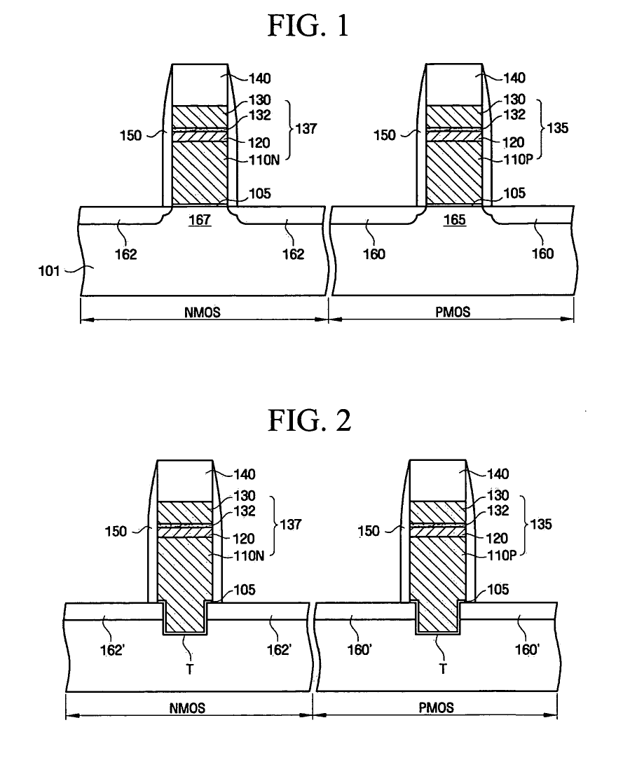

FIG. 2 is a diagram illustrating the semiconductor device including a recess channel transistor to which the multilayer structure is applied according to example embodiments. Unlike FIG. 1, a channel region between P type source/drain regions 106′ of the PMOS transistor and a channel region between N type source/drain regions 162′ of the NMOS transistor may be formed along an outer periphery of a trench T that is a recess formed in the semiconductor substrate 101, respectively. Even though the design rule of the gate line of the transistor decreases, a sufficient channel length may be realized. Other components may be substantially the same as those of the semiconductor device described with reference to FIG. 1.

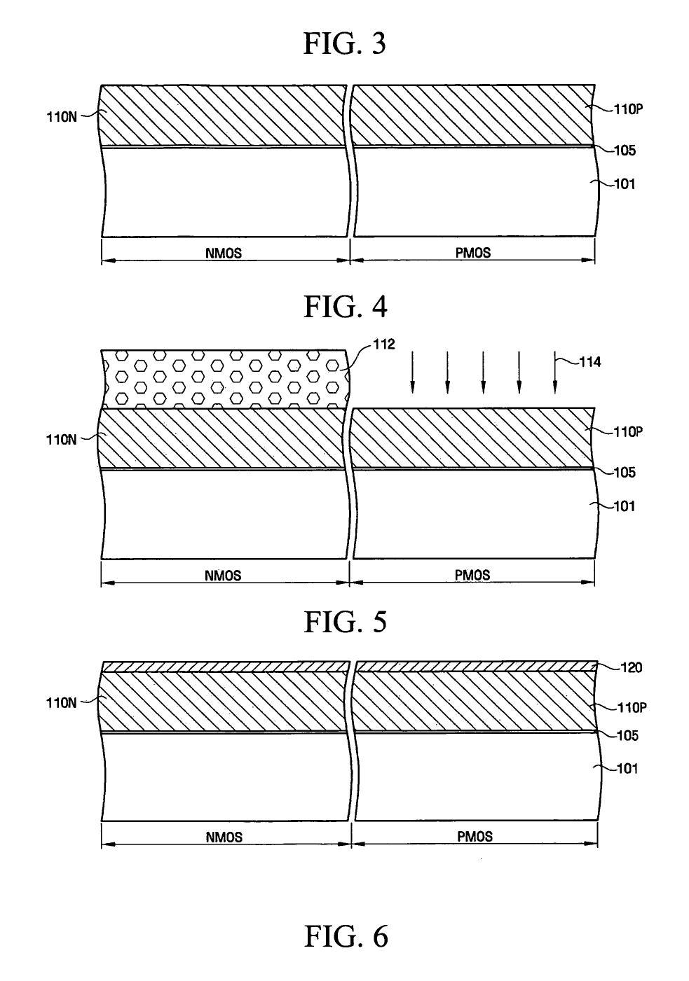

Hereinafter, with reference to FIGS. 3 through 8, a method of fabricating the semiconductor device shown in FIG. 1 will be described. With reference to FIG. 3, an active region may be defined by forming a device division region (not shown) in the semiconductor substrate 101, and then the gate insulating layer 105 may be formed on the semiconductor substrate 101. As for the substrate 101, a substrate formed of at least one semiconductor material selected from the group including Si, Ge, SiGe, GaP, GaAs, SiC, SiGeC, InAs and/or InP, and/or a SOI (Silicon On Insulator) substrate may be used.

A silicon oxidized layer, formed by thermally oxidizing the substrate 101, SiON, GexOyNz, GexSiyOz, a relatively high dielectric substance, a combination of these and/or a laminated layer in which these are sequentially laminated may be used in forming the gate insulating layer 105. The relatively high dielectric substance may be, for example, HfO₂, ZrO₂, Al₂O₃, Ta₂O₅, hafnium silicate, zirconium silicate and/or a composite layer of these. A polycrystalline semiconductor layer doped with N type impurities, for example, the polycrystalline silicon layer 110N, may be formed on the gate insulating layer 105. The polycrystalline semiconductor layer doped with N type impurities may be formed as a polycrystalline silicon layer and then doped with N type impurities by ion-implantation, or the polycrystalline silicon may be doped with N type impurities in situ during deposition of the polycrystalline silicon layer. The N type impurities may be phosphorus (P) and/or arsenic (As).

With reference to FIG. 4, a photoresist pattern 112 may be formed to mask a region, among active regions, in which the NMOS is formed. The polycrystalline silicon layer 110P doped with P type impurities may be formed by doping with P type impurities 114 and ion-implantation by using the photoresist pattern 112 as an ion implantation mask. The P type impurities may be boron (B), boron fluoride (BF₂) and Indium (In). The concentration of P type impurities may be higher than that of the concentration of N type impurities doped earlier in the process, so that the entire conductive type may appear to be P type. As shown in FIG. 4, a dual polycrystalline silicon layer, composed of the polycrystalline silicon layer 110N doped with N type impurities and the polycrystalline silicon layer 110P doped with P type impurities, may be formed on the semiconductor substrate 101.

The dual polycrystalline silicon layer may be formed by using two sheets of mask exposing the NMOS transistor region and the PMOS transistor region, respectively, and implanting N type impurities and T type impurities, respectively. As described in FIGS. 3 and 4, it may be possible to simplify the process and reduce the fabricating cost by using only one sheet of mask. A relatively quick nitriding treatment and/or cleaning process may be performed.

With reference to FIG. 5, the ohmic contact layer 120 may be formed on top of the polycrystalline semiconductor layers 110N and 110P. This ohmic contact layer 120 may be formed of a two-component metal layer (W₁₋ₓMₓ, x=about 0.01 to about 0.55) including tungsten and a non-tungsten metal. According to example embodiments, this two-component metal layer may be formed by, for example, physical vapor deposition using a two-component composite target (W₁₋ₓMₓ, x=about 0.01 to about 0.55) including tungsten and a non-tungsten metal; however, the method of forming the two-component metal layer is not limited thereto. Temperature for deposition may be in the range of about 0° C. to about 900° C.

According to example embodiments, a two-component metal layer may be formed as follows. A bilayer may be formed by sequentially laminating a tungsten layer and a non-tungsten metal layer on the polycrystalline semiconductor layer doped with first conductive type impurities. Even though the tungsten layer may be formed before the non-tungsten metal layer on the polycrystalline semiconductor layer, for improved resistance characteristics, the non-tungsten metal layer may be formed before the tungsten layer. The tungsten and the non-tungsten metal layers may be formed by deposition, (e.g., PVE, CVD, PECVE and/or ALD), but the method of forming the tungsten and the non-tungsten metal layers is not limited thereto. The tungsten source gas may be WF₆, WCl₆ and/or W(CO)₆, and the non-tungsten metal source gas may be TiCl₄, TDMAT, TEMAT, TDEAT, TDMAH, TDEAH, TEMAH, HfCl₄, TDMAZ, TDEAZ, TEMAZ and/or ZrCl₄; however, the tungsten and non-tungsten metal source gases are not limited thereto. The tungsten layer and the non-tungsten metal layer may be deposited in a temperature range of about 0° C. to about 900° C., respectively. A tungsten layer A and a non-tungsten metal layer B may be formed having a thickness in the range of about 5 Å to about 100 Å, respectively, and the thickness ratio B/A may be in a range of about 0.01 to about 1.2.

Annealing may be performed on the formed bilayer. A homogeneous two-component metal layer may be formed as the tungsten layer and the non-tungsten metal layer are mixed during annealing. The annealing process may be performed at a temperature of about 200° C. to about 900° C. In accordance with the conditions of the annealing process, a portion of the two-component metal layer, specifically, the portion of the two-component metal layer adjacent to the interface of the polycrystalline semiconductor layer doped with impurities, may react with the polycrystalline semiconductor layer, so that a portion of the two-component metal layer may be converted into a ternary silicide layer.

The two-component metal layer may undergo an additional annealing process, so that a portion of the entire two-component metal layer may be silicidized. As the portion of the two-component metal layer adjacent to the polycrystalline semiconductor layer is silicidized by annealing, a ternary silicide layer (MₓW₁₋ₓSi_{y}, x=about 0.01 to about 0.55) may be formed. The annealing process may be performed at least once and at any time after the two-component metal layer is formed. The annealing process may be performed as a separate process from silicidization, but also as a subsequent process. For example, a thermal process may be performed while forming wiring lines to enable input and output of electrical signals, while forming passivation on a substrate, and while packaging a substrate. This annealing process may be performed at a temperature in a range of about 400° C. to about 1100° C. so that the two-component metal layer is silicidized.

The method of fabricating the ohmic contact layer 120 may be a method of depositing a ternary silicide layer with CVD and/or ALD using non-tungsten metal source gas and tungsten source gas. The tungsten source gas may be WF₆, WCl₆ and/or W(CO)₆, the non-tungsten metal source gas may be TiCl₄, TDMAT, TEMAT, TDEAT, TDMAH, TDEAH, TEMAH, HfCl₄, TDMAZ, TDEAZ, TEMAZ and/or ZrCl₄, and the silicon source gas may be SiH₄, SiH₂Cl₂ and/or Si(OC₂H₅)₄; however, the tungsten, non-tungsten metal and silicon source gases are not limited thereto. The condition of the source gases used in the process of fabricating these metal layers and the silicide layer, for example, flow rate, temperature, pressure, and/or other conditions, may change due to different kinds of deposition apparatus and/or the flow rate, temperature, pressure and/or any other conditions may change in forming the metal layers and the silicide layer suitable for example embodiments within the idea and scope of the claims.

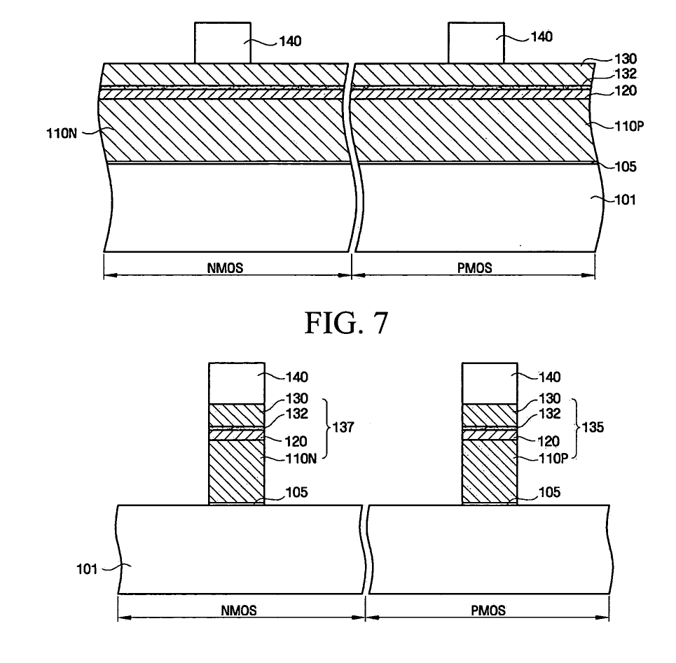

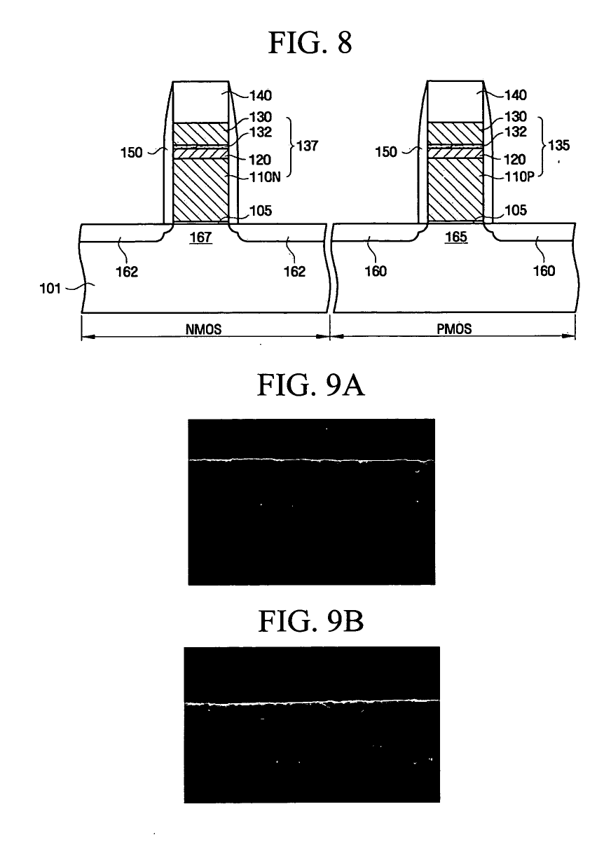

With reference to FIG. 6, the metal barrier layer 132 and the refractory metal layer 130 may be sequentially formed on the ohmic contact layer 120. The hard mask 140 may be formed on the refractory metal layer 130 to define the gate electrode. The hard mask 140 may be formed of a silicon nitride layer and/or any other suitable layer. With reference to FIG. 7, by using the hard mask 140 as an etching mask, the refractory metal layer 130, the metal barrier layer 124, the ohmic contact layer 120, the polycrystalline silicon layers 110N and 110P and the gate insulating layer 105 may be patterned so as to complete the gate electrode. With reference to FIG. 8, P type impurities may be implanted in the PMOS region and N type impurities may be implanted in the NMOS region, respectively, to form the P type source/drain region 160 and the N type source/drain region 162, respectively. Each source/drain region may have an LDD structure. The flat channel type PMOS transistor and NMOS transistor, including the P type source/drain region 160 and the N type source/drain region 162, may be completed.

The method of fabricating a semiconductor device may further include forming a capacitor, forming wiring lines including bit lines which enable electrical signals to be input to or output from the PMOS transistor and the NMOS transistor, forming passivation on the substrate and packaging the substrate. The order of forming a capacitor and forming wiring lines may vary within the purpose of example embodiments. Hereinafter, the evaluation of the characteristics of the semiconductor device according to example embodiments will be described.

A semiconductor device including a gate formed of a tungsten layer (W)/tungsten nitride (WN) layer/ohmic contact layer/p⁺ polycrystalline silicon layer may be fabricated and sheet resistance may be measured. The interface shape may be observed through a scanning electron microscope (SEM), and then the results are shown in Table 1. In Table 1, if the interface shape is improved, indication ◯ follows, and if the interface shape is not improved, indication X follows.

In test sample 1, the two-component metal layer may be deposited on the polycrystalline silicon layer formed on the gate insulating layer by a PVD method using a composite target having a composition of Ti_{0.1} W_{0.9}. WN and W may be sequentially deposited, and then a hard mask may be formed and a gate may be patterned. The two-component metal layer may be annealed at about 850° C. so as to be silicidized. Sheet resistance may have been measured before and after the silicidization of the two-component metal layer, respectively, and the interface shape may have been observed after the silicidization.

In test sample 2, a W layer and a Ti layer may be sequentially deposited on the polycrystalline silicon layer formed on the gate insulating layer. The thickness of the W layer and Ti layer may be about 50 Å and about 30 Å, respectively, and the thickness ratio (Ti/W) may be about 0.6. The polycrystalline silicon layer may be annealed at about 450° C. so as to form the two-component metal layer. WN and W may be sequentially deposited, and then a hard mask may be formed and a gate may be patterned. The two-component metal layer may be annealed at about 850° C. so as to be silicidized. Sheet resistance may have been measured before and after the silicidization of the two-component metal layer, respectively, and the interface shape may have been observed after the silicidization.

In order to form a comparative example 1, a Ti layer may be deposited on the polycrystalline silicon layer formed on the gate insulating layer. WN and W may be sequentially deposited, and then a hard mask may be formed and a gate may be patterned. The two-component metal layer may be annealed at 850° C. so as to be silicidized. Sheet resistance may have been measured before and after the silicidization of the two-component metal layer, respectively, and the interface shape may have been observed after the silicidization.

TABLE 1

Sheet resistance
(Rs) (Ω/SQ)

| | Before | After | Interface |
|---|---|---|---|
| | silicidization | silicidization | shape |
| Test sample 1 | 6.2 | 5.3 | ◯ |
| Test sample 2 | 6.9 | 5.6 | ◯ |
| Comparative | 9.0 | 8.8 | X |
| sample 1 | | | |

As shown in Table 1, the test samples 1 and 2 fabricated according to example embodiments may be improved in terms of sheet resistance, as compared to the comparative sample 1. Sheet resistance measured after the silicidization may be further decreased, as compared to sheet resistance before the silicidization.

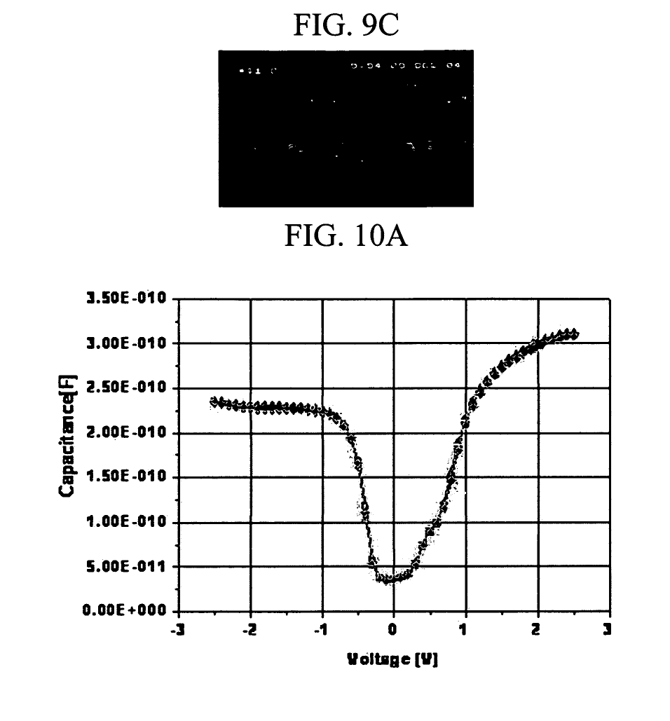

With reference to FIGS. 9A to 9C, when the interface shape of the polycrystalline silicon layer and the ohmic contact layer is captured, test sample 1 (FIG. 9A) and test sample 2 (FIG. 9B) may be improved in terms of roughness of the interface.

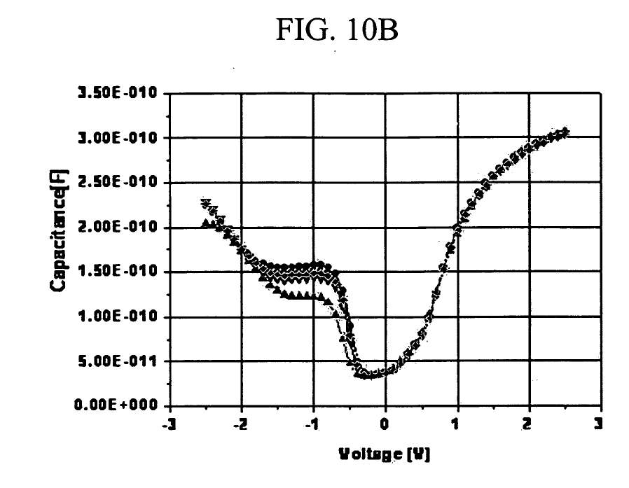

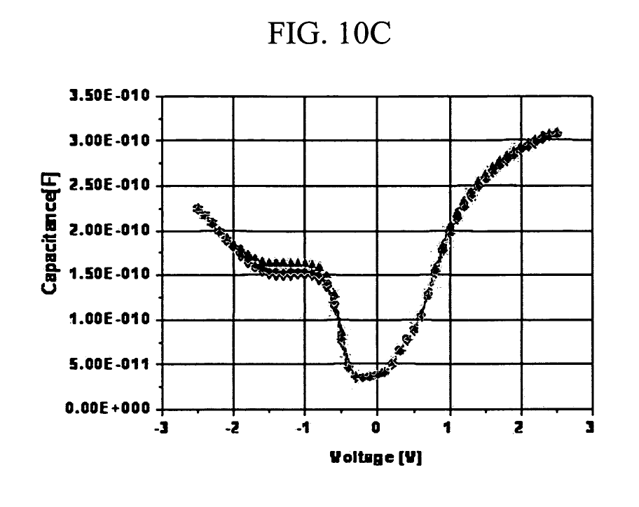

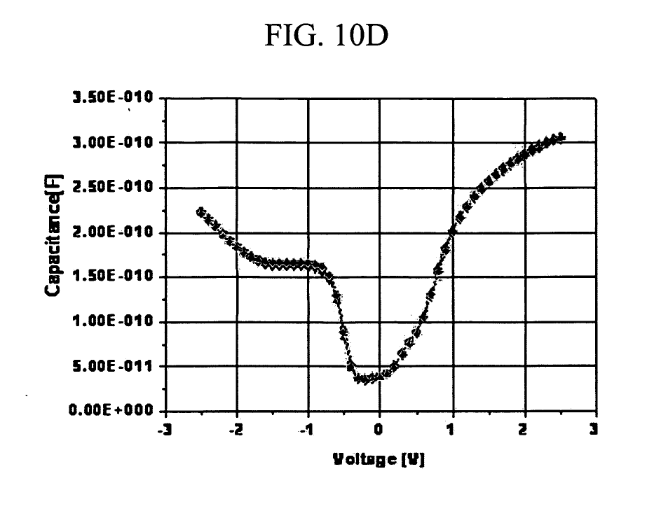

Hereinafter, FIGS. 10A to 10D illustrate evaluation of the C-V characteristic of the semiconductor device according to example embodiments. FIGS. 10A to 10D have been obtained by measuring the C-V characteristic of the semiconductor device having a gate formed of a refractory metal layer/metal barrier layer/ohmic contact layer/polycrystalline silicon layer. FIG. 10A is about test sample 3 according to example embodiments, and is a graph illustrating the result of evaluating the C-V characteristic of a PMOS transistor in a semiconductor device having a dual gate formed of W/WNₓ/Ti_{0.1}W_{0.9}Si polycrystalline silicon layer. FIGS. 10B to 10D show comparative samples 2 to 4, respectively, and are graphs illustrating the result of evaluating the C-V characteristic of a PMOS transistor in a semiconductor device having a dual gate formed of W/WNₓ/TiSiₓ polycrystalline silicon layer (comparative sample 2), W/TiNₓ/WSiₓ polycrystalline silicon layer (comparative sample 3), W/TiNₓ/TiSiₓ polycrystalline silicon layer (comparative sample 4), respectively. The C-V characteristic may be measured at five different points of a semiconductor wafer for each sample.

With reference to FIG. 10A, there may be improvement of PMOS inversion capacitance in the semiconductor device having the gate formed according to example embodiments. In the case of FIGS. 10B to 10D illustrating the C-V characteristic of the comparative samples 2 to 4, deterioration may be found in the inversion capacitance. In particular, in the case of comparative sample 2 (FIG. 10B), a relatively large variation may be found in the inversion capacitance values depending on where the inversion capacitance is measured.

As described above, the semiconductor device according to example embodiments may be relatively stable at higher temperatures and capable of not only keeping resistance characteristics of a gate electrode within a desired range, but also improving characteristics, for example, inversion capacitance. Therefore, the semiconductor device may have improved reliability.

Although example embodiments have been described in connection with example embodiments, it will be apparent to those skilled in the art that various modifications and changes may be made thereto without departing from the scope and spirit of the claims. Therefore, it should be understood that the above embodiments are not limited, but illustrative of all example embodiments.

What is claimed is:

1. A multilayer gate electrode comprising:
a polycrystalline semiconductor layer doped with conductive type impurities on a first gate insulating layer;
an ohmic contact layer including tungsten (W₁₋ₓ) and non-tungsten metal (Mₓ, x=about 0.01 to about 0.55) on the polycrystalline semiconductor layer;
a metal barrier layer on the ohmic contact layer; and
a refractory metal layer on the metal barrier layer.

2. A semiconductor device including a conductive type transistor, the conductive type transistor comprising:
a semiconductor substrate;
a first conductive type source/drain region in the semiconductor substrate;
the first gate insulating layer on a channel region between the source/drain regions; and
the multilayer gate electrode of claim 1.

3. The semiconductor device of claim 2, further comprising:
a second conductive type source/drain region in the semiconductor substrate; and
a second gate insulating layer on a channel region between the source/drain regions.

4. The multilayer gate electrode of claim 1, wherein the ohmic contact layer has a ternary silicide layer including tungsten and non-tungsten metal on the interface with the polycrystalline semiconductor layer.

5. The multilayer gate electrode of claim 1, wherein the ohmic contact layer is a ternary silicide layer including the tungsten and non-tungsten metal.

6. The multilayer gate electrode of claim 1, wherein the non-tungsten metal is at least one selected from the group consisting of Ti, Zr, and Hf.

7. The multilayer gate electrode of claim 1, wherein the refractory metal layer is formed of at least one selected from the group consisting of tungsten (W), rhenium (Re), tantalum (Ta), osmium (Os), molybdenum (Mo), niobium (Nb), vanadium (V), hafnium (Hf), zirconium (Zr), and titanium (Ti).

8. The multilayer gate electrode of claim 1, wherein the metal barrier layer is formed of at least one selected from the group consisting of WNₓ, TaNₓ, and TiNₓ.

9. The multilayer gate electrode of claim 1, wherein the channel region is a recessed channel region in the semiconductor substrate.

10. A method of fabricating a multilayer gate electrode comprising:
forming a polycrystalline semiconductor layer doped with first conductive type impurities on a gate insulating layer;
forming an ohmic contact layer including tungsten (W₁₋ₓ) and non-tungsten metal (Mx, x=about 0.01 to about 0.55) on the polycrystalline semiconductor layer;
forming a metal barrier layer on the ohmic contact layer;
forming a refractory metal layer on the metal barrier layer; and
sequentially patterning the refractory metal layer, the metal barrier layer, the ohmic contact layer, the polycrystalline semiconductor layer and the gate insulating layer.

11. A method of fabricating a semiconductor device including a conductive type transistor, further comprising:
providing a semiconductor substrate in which the gate insulating layer is formed; and
forming a multilayer gate electrode according to claim 10.

12. The method of claim 11, further comprising:
forming the polycrystalline semiconductor layer doped with second conductive type impurities on the gate insulating layer.

13. The method of claim 10, wherein forming the ohmic contact layer includes depositing a composite target composed of tungsten and non-tungsten metal.

14. The method of claim 13, further comprising:
annealing the ohmic contact layer to form a silicidized ohmic contact layer.

15. The method of claim 10, wherein forming the ohmic contact layer includes:
forming a bilayer including a tungsten layer and a non-tungsten metal layer on the polycrystalline semiconductor layer; and
annealing the bilayer.

16. The method of claim 15, wherein forming the bilayer includes sequentially laminating the tungsten layer and the non-tungsten metal layer on the polycrystalline semiconductor layer.

17. The method of claim 15, wherein the thickness ratio (B/A) of the tungsten layer A and the non-tungsten metal layer B is in a range of about 0.01 to about 1.2.

18. The method of claim 15, further comprising:
annealing the ohmic contact layer to form a silicidized ohmic contact layer.

19. The method of claim 10, wherein forming the ohmic contact layer includes forming the ohmic contact layer by a CVD method or an ALD method using tungsten source gas, non-tungsten metal source gas, and silicon source gas.

20. The method of claim 10, further comprising:
annealing the ohmic contact layer to form a silicidized ohmic contact layer.

21. The method of claim 11, further comprising:
forming a capacitor after forming the conductive type transistor;
forming wiring lines which allow electrical signals to be input to and output from the conductive type transistor;
forming a passivation layer on the substrate; and
packaging the substrate.

22. The method of claim 10, wherein the non-tungsten metal is any one selected from the group including Ti, Zr and Hf.

23. The method of claim 10, wherein the refractory metal layer is formed of at least one of metals selected from the group including tungsten (W), rhenium (Re), tantalum (Ta), osmium (Os), molybdenum (Mo), niobium (Nb), vanadium (V), hafnium (Hf), zirconium (Zr), titanium (Ti).

24. The method of claim 10, wherein providing the semiconductor substrate includes providing a recessed channel trench.
